(19) United States
(12) Patent Application Publication
(10) Pub. No.: US 2026/0333918 A1
(43) Pub. Date: Oct. 22, 2026

(54) IMAGE SENSORS HAVING GRIDS

(71) Applicant: Samsung Electronics Co., Ltd., Suwon -si (KR)

(72) Inventors: Jaepil Jo, Suwon -si (KR); Inyong Park, Suwon -si (KR); Shinho Lee, Suwon -si (KR)

(73) Assignee: Samsung Electronics Co., Ltd., Suwon-si (KR)

(21) Appl. No.: 19/648,288

(22) Filed: Apr. 15, 2026

(30) Foreign Application Priority Data
Apr. 22, 2025 (KR) 10-2025-0052186

(51) Int. Cl. H10F 39/00

(52) U.S. Cl. CPC H10F 39/807; H10F 39/8053

(57) ABSTRACT

An image sensor includes color filters disposed on a substrate and a separation structure, grids disposed between the color filters and including air gaps, and an upper capping layer covering upper surfaces of the color filters and the grids. The grids include first grids extending in a first horizontal direction and arranged in a plurality of rows, and second grids extending in a second horizontal direction, intersecting the first horizontal direction, and arranged in a plurality of columns. The first grids and the second grids are disposed alternately in the first horizontal direction and the second horizontal direction. The first grids include a first grid group disposed in a first row, and a second grid group disposed in a second row, adjacent to the first row, and the first grid group is disposed to be offset from the second grid group in the first horizontal direction.

### CROSS-REFERENCE TO RELATED APPLICATIONS

This present application claims priority to and the benefit under 35 U.S.C. § 119(a)-(d) of Korean Patent Application No. 10-2025-0052186, filed on Apr. 22, 2025, in the Korean Intellectual Property Office, the entire disclosure of which is incorporated herein by reference.

### FIELD

The present disclosed concepts relate to an image sensor including a grid.

### BACKGROUND

Image sensors may be semiconductor-based sensors receiving light to generate an electric signal, and may include a pixel array having a plurality of pixels, and a logic circuit for driving the pixel array and generating an image. Each of the pixels may include a photodiode, and a pixel circuit for converting charges generated by the photodiode into an electric signal.

### SUMMARY

An image sensor according to example embodiments may include photodiodes disposed in a substrate; a separation structure disposed in the substrate and between the photodiodes; color filters disposed on the substrate and the separation structure; grids disposed between the color filters and including air gaps, wherein the grids include first grids extending in a first horizontal direction and arranged in a plurality of rows, and second grids extending in a second horizontal direction, intersecting the first horizontal direction, and arranged in a plurality of columns; and an upper capping layer covering upper surfaces of the color filters and the grids. The first grids and the second grids may be alternately disposed in the first horizontal direction and the second horizontal direction. The first grids may include a first grid group disposed in a first row, and a second grid group disposed in a second row, adjacent to the first row. The second grids may include a third grid group disposed in a first column, intersecting the first row and the second row, and a fourth grid group disposed in a second column, adjacent to the first column. The first grid group may be disposed to be offset from the second grid group in the first horizontal direction.

An image sensor according to example embodiments may include photodiodes disposed in a substrate; a separation structure disposed in the substrate and between the photodiodes; color filters disposed on the substrate and the separation structure; grids disposed between the color filters and including air gaps, wherein the grids include first grids extending in a first horizontal direction and arranged in a plurality of rows, and second grids extending in a second horizontal direction, intersecting the first horizontal direction, and arranged in a plurality of columns; and an upper capping layer covering upper surfaces of the color filters and the grids. The first grids and the second grids may be alternately disposed in the first horizontal direction and the second horizontal direction. The color filters may include a first color filter, a second color filter, adjacent to the first color filter in the first horizontal direction, and a third color filter, adjacent to the first color filter in the second horizontal direction, intersecting the first horizontal direction. The first color filter may include a first protrusion contacting the second color filter and extending in the first horizontal direction, and a second protrusion contacting the third color filter and extending in the second horizontal direction. The first protrusion of the first color filter may be spaced apart from the third color filter. The second protrusion of the first color filter may be spaced apart from the second color filter. The first color filter and the second color filter may be mirror-symmetrical with respect to a central axis in the second horizontal direction between the first color filter and the second color filter.

An image sensor according to example embodiments may include a lower structure including a first circuit element; and an upper structure joined to the lower structure on the lower structure. The upper structure may include a substrate including a first surface and a second surface, opposite to one another; photodiodes disposed in the substrate; a separation structure disposed in the substrate and between the photodiodes; a second circuit element between the first surface of the substrate and the lower structure; a first antireflection layer disposed on the second surface of the substrate and the separation structure; color filters disposed on the first antireflection layer; grids disposed between the color filters and including air gaps, wherein the grids include first grids extending in a first horizontal direction and arranged in a plurality of rows, and second grids extending in a second horizontal direction, intersecting the first horizontal direction, and arranged in a plurality of columns; and an upper capping layer covering upper surfaces of the color filters and the grids. The first grids and the second grids may be alternately disposed in the first horizontal direction and the second horizontal direction. The first grids may include a first grid group disposed in a first row, and a second grid group disposed in a second row, adjacent to the first row. The second grids may include a third grid group disposed in a first column, intersecting the first row and the second row, and a fourth grid group disposed in a second column, adjacent to the first column. The first grid group may be disposed to be offset from the second grid group in the first

### BRIEF DESCRIPTION OF DRAWINGS

The and other aspects, features, and advantages of the present disclosed concepts will be more clearly understood from the following detailed description, taken in conjunction with the accompanying drawings, in which:

FIG. 1 is a block diagram briefly illustrating an image sensor according to example embodiments.

FIG. 2 is a view briefly illustrating an example of a pixel circuit of an image sensor according to example embodiments.

FIG. 3 is a plan view schematically illustrating an image sensor according to example embodiments.

FIG. 4 is an enlarged view of the image sensor illustrated in FIG. 3.

FIG. 5 is a vertical cross-sectional view of the image sensor illustrated in FIG. 3, taken along line I-I′.

FIG. 6 is an enlarged view of the image sensor illustrated in FIG. 5.

FIGS. 7 to 16 are vertical cross-sectional views of image sensors according to example embodiments.

FIGS. 17 and 18 are plan views of image sensors according to example embodiments.

FIGS. 19 to 21 illustrate various arrangements of color filters of an image sensor according to example embodiments.

FIG. 22A is a schematic plan view of an image sensor according to example embodiments.

FIG. 22B is an enlarged view of the image sensor illustrated in FIG. 22A.

FIG. 23A is a schematic plan view of an image sensor according to example embodiments.

FIG. 23B is an enlarged view of the image sensor illustrated in FIG. 23A.

FIG. 24 is a vertical cross-sectional view of an image sensor according to example embodiments.

FIG. 25 is a flow chart illustrating a method of manufacturing an image sensor according to example embodiments.

FIGS. 26 to 28 are cross-sectional views illustrated according to a process sequence illustrating a method of manufacturing an image sensor according to example embodiments.

FIG. 29 is a graph illustrating quantum efficiency (QE) for blue light, green light, and red light according to wavelength in an image sensor according to an inventive example and a comparative example.

### DETAILED DESCRIPTION

Hereinafter, terms such as ‘on,’ ‘upper portion,’ ‘upper surface,’ ‘below,’ ‘lower portion,’ ‘lower surface,’ ‘side surface,’ ‘upper end,’ ‘lower end,’ or the like can be understood to refer to the drawings, except in cases in which they are indicated separately by drawing symbols.

The present disclosed concepts provide an image sensor including a grid including an air gap.

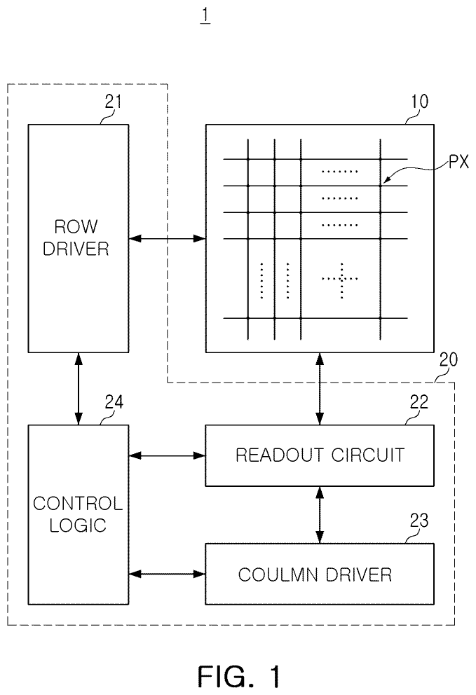

First, with reference to FIG. 1, an example of an image sensor according to example embodiments will be described. FIG. 1 is a block diagram briefly illustrating an image sensor according to example embodiments.

Referring to FIG. 1, an image sensor 1 may include a pixel array 10, a logic circuit 20, and the like. The pixel array 10 may include a plurality of pixels PX disposed in an array form along a plurality of rows and a plurality of columns. Each of the plurality of pixels PX may include at least one photodiode generating a charge in response to light, a pixel circuit generating a pixel signal corresponding to the charge generated by the photodiode, and the like. The photodiode may include a photodiode formed of a semiconductor material, and/or an organic photodiode formed of an organic material, or the like.

For example, the pixel circuit may include a floating diffusion, a transmission transistor, a reset transistor, a driving transistor, a select transistor, or the like. A configuration of the pixels PX may be changed depending on embodiments. For example, each of the pixels PX may include an organic photodiode including an organic material, or may be implemented as a digital pixel. When the pixels PX are implemented as digital pixels, each of the pixels PX may include an analog-to-digital converter for outputting a digital pixel signal.

The logic circuit 20 may include circuits for controlling the pixel array 10. For example, the logic circuit 20 may include a row driver 21, a readout circuit 22, a column driver 23, a control logic 24, and the like. The row driver 21 may drive the pixel array 10 in units of row lines. For example, the row driver 21 may generate a transmission control signal for controlling a transmission transistor of a pixel circuit, a reset control signal for controlling a reset transistor, a select control signal for controlling a select transistor, or the like, and input the same to the pixel array 10 in row line units.

The readout circuit 22 may include a correlated double sampler (CDS), an analog-Attorney to-digital converter (ADC), or the like. The correlated double samplers may be connected to the pixels PX through column lines. The correlated double samplers may read pixel signals from the pixels PX connected to a row line selected by a row line select signal of the row driver 21 through the column lines. The analog-to-digital converter may convert a pixel signal detected by the correlated double sampler into a digital pixel signal, and transmit the same to the column driver 23.

The column driver 23 may include a latch circuit or a buffer circuit and an amplifier circuit, or the like, which may temporarily store a digital pixel signal, and may process a digital pixel signal received from the readout circuit 22. The row driver 21, the readout circuit 22, and the column driver 23 may be controlled by the control logic 24. The control logic 24 may include a timing controller or the like for controlling operation timing of the row driver 21, the readout circuit 22, and the column driver 23.

Among the pixels PX, the pixels PX disposed in the same position in a horizontal direction may share the same column line. In an example, the pixels PX disposed in the same position in a vertical direction may be simultaneously selected by the row driver 21, and may output pixel signals through the column lines. In an example, the readout circuit 22 may simultaneously acquire pixel signals from the pixels PX selected by the row driver 21 through the column lines. The pixel signal may include a reset voltage and a pixel voltage, and the pixel voltage may be a voltage in which charges generated in response to light in each of the pixels PX are reflected in the reset voltage.

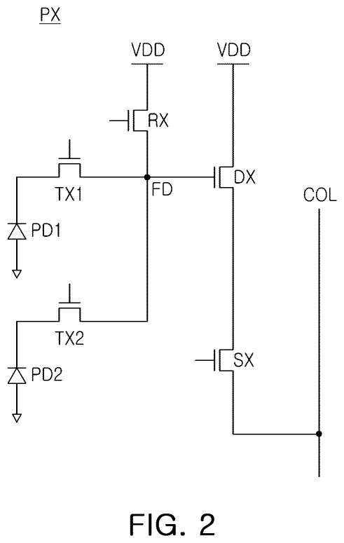

Next, with reference to FIG. 2, an example of a pixel circuit of an image sensor according to embodiments will be described. FIG. 2 is a view briefly illustrating an example of a pixel circuit of an image sensor according to example embodiments.

In an example, referring to FIGS. 1 and 2, each of the plurality of pixels PX may include photodiodes PD1 and PD2 and a pixel circuit, and the pixel circuit may include transmission transistors TX1 and TX2, a reset transistor RX, a select transistor SX, a driving transistor DX, and the like.

The photodiodes PD1 and PD2 may generate and accumulate charges in response to light incident from an outside. The pixel circuit may further include a floating diffusion region FD in which the charges generated from the photodiodes PD1 and PD2 are accumulated.

The photodiodes PD1 and PD2 may be replaced with a phototransistor, a photogate, a pinned photodiode, or the like, depending on embodiments. The photodiodes PD1 and PD2 may also be referred to as a “photodiode.” Therefore, the photodiode may be the photodiode, the phototransistor, the photogate, or the pinned photodiode.

In embodiments, the transmission transistors TX1 and TX2 and the photodiodes PD1 and PD2 may share one floating diffusion region FD. Depending on embodiments, the floating diffusion regions FD may not be shared, and the transmission transistors TX1 and TX2 may be connected to separate floating diffusion regions FD, respectively.

The transmission transistors TX1 and TX2 may transfer the charges generated from the photodiodes PD1 and PD2 to the floating diffusion region FD, respectively. The floating diffusion region FD may store the charges generated from the photodiodes PD1 and PD2. A voltage output by the driving transistor DX may be changed depending on amounts of charges accumulated in the floating diffusion region FD.

The reset transistor RX may reset a voltage of the floating diffusion region FD by removing the charges accumulated in the floating diffusion region FD. A drain electrode of the reset transistor RX may be connected to the floating diffusion region FD, and a source electrode of the reset transistor RX may be connected to a power supply voltage VDD. When the reset transistor RX is turned on, the power supply voltage VDD connected to the source electrode of the reset transistor RX may be applied to the floating diffusion region FD, and the charges accumulated in the floating diffusion region FD may be removed.

The driving transistor DX may operate as a source follower buffer amplifier. The driving transistor DX may amplify a change in voltage of the floating diffusion region FD, and may output the same to a column line COL. The select transistor SX may select pixels PX to be read in rows. When the select transistor SX is turned on, a voltage of the driving transistor DX may be output to the column line COL. When the select transistor SX is turned on, a reset voltage or a pixel voltage may be output through the column line COL.

The pixel circuit described with reference to FIG. 2 is only illustrative, and is not necessarily limited thereto.

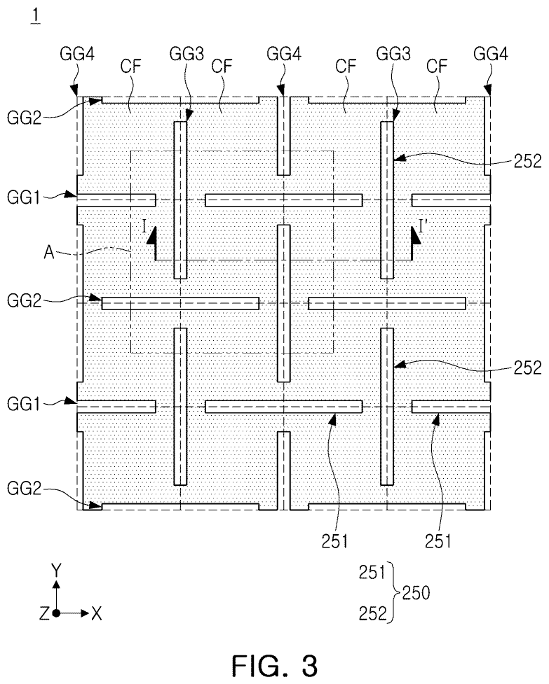

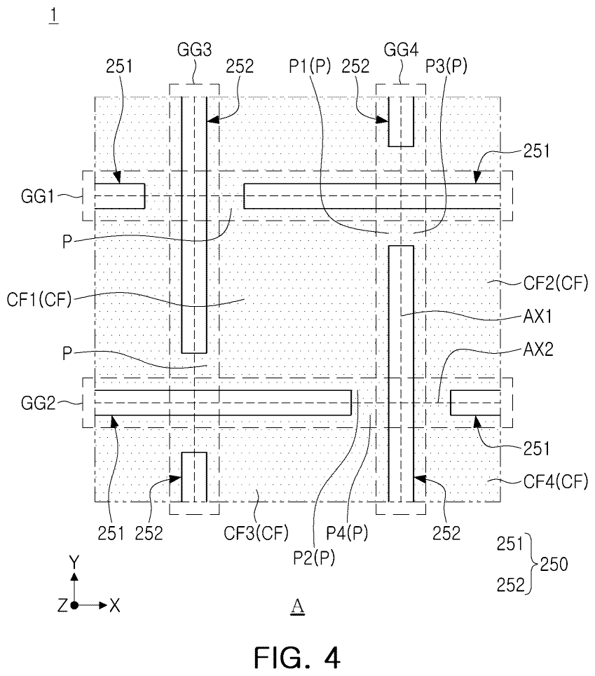

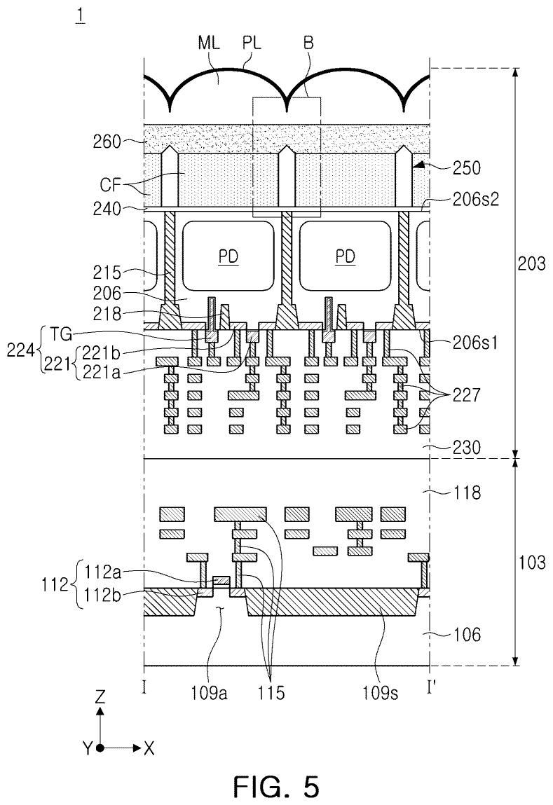

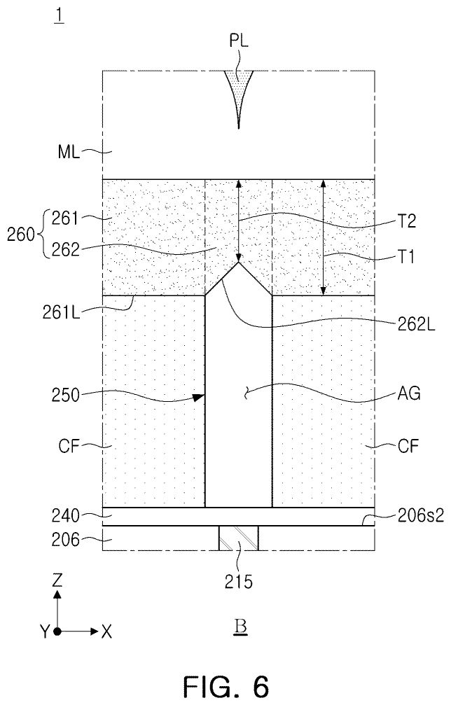

Next, an example of an image sensor structure according to example embodiments will be described with reference to FIGS. 3 to 6. FIG. 3 is a plan view schematically illustrating an image sensor according to example embodiments. FIG. 4 is an enlarged view of the image sensor illustrated in FIG. 3. FIG. 5 is a vertical cross-sectional view of the image sensor illustrated in FIG. 3, taken along line I-I′. FIG. 6 is an enlarged view of the image sensor illustrated in FIG. 5.

Referring to FIGS. 3 to 6, an image sensor 1 according to embodiments may have a stacked chip structure to which at least two chips are applied. For example, the image sensor 1 may include a lower structure 103 and an upper structure 203 on the lower structure 103. The lower structure 103 may be a logic chip, and the upper structure 203 may be an image sensor chip. In another example, the lower structure 103 may be a stacked structure including a logic chip and a memory chip.

The lower structure 103 of the image sensor 1 may include a first substrate 106, a device isolation film 109s defining an active region 109a on the first substrate 106, a first circuit element 112 and a first interconnection structure 115, on the first substrate 106, and a first insulating structure 118 covering the first circuit element 112 and the first interconnection structure 115 on the first substrate 106. The first interconnection structure 115 may be electrically connected to the first circuit element 112.

The first substrate 106 may be a semiconductor substrate. For example, the first substrate 106 may be a substrate formed of a semiconductor material, for example, a single crystal silicon substrate. The first circuit element 112 may include an element such as a transistor including a gate 112a and a source/drain 112b.

The upper structure 203 may include a second substrate 206 having a first surface 206s1 and a second surface 206s2, opposing one another, an element isolation film 218 disposed on the first surface 206s1 of the second substrate 206 and defining an active region, a second circuit element 224 and a second interconnection structure 227, disposed between the first surface 206s1 of the second substrate 206 and the lower structure 103, and a second insulating structure 230 covering the second circuit element 224 and the second interconnection structure 227 between the first surface 206s1 of the second substrate 206 and the lower structure 103. The second interconnection structure 227 may be electrically connected to the second circuit element 224. The first surface 206s1 of the second substrate 206 may face the lower structure 103. The element isolation film 218 may be formed of an insulating material such as silicon oxide or the like. The second circuit element 224 and the second interconnection structure 227, disposed below the first surface 206s1 of the second substrate 206, may constitute a circuit interconnection structure. Therefore, the circuit interconnection structure may be disposed below the first surface 206s1 of the second substrate 206.

The second substrate 206 may be a semiconductor substrate. For example, the second substrate 206 may be a substrate formed of a semiconductor material, for example, a single crystal silicon substrate.

Photodiodes PD may generate and accumulate charges corresponding to incident light. For example, the photodiodes PD may include a photodiode, a phototransistor, a photogate, a pinned photodiode (PPD), and a combination thereof.

Each of the photodiodes PD may be a photodiode formed in the second substrate 206. Therefore, a plurality of pixel regions may include a photodiode, respectively. The plurality of pixel regions may also be referred to as the photodiodes PD or photodiodes, respectively.

The upper structure 203 may further include a separation structure 215. The separation structure 215 may be disposed to surround each of the photodiodes PD. The separation structure 215 may vertically penetrate at least a portion of the second substrate 206. For example, the separation structure 215 may vertically penetrate the second substrate 206. In embodiments, a horizontal width of the separation structure 215 on the first surface 206s1 of the second substrate 206 may be greater than a horizontal width of the separation structure 215 on the second surface 206s2 of the second substrate 206.

To minimize or prevent interference or influence between photodiodes PD, the separation structure 215 may include a material capable of applying a voltage to the separation structure 215. For example, the separation structure 215 may include a conductive material, for example, doped polysilicon. In an example, the separation structure 215 may include doped polysilicon having an N-type conductivity-type. In another example, the separation structure 215 may include doped polysilicon having a P-type conductivity-type. In embodiments, the separation structure 215 may be formed as a plurality of layers. For example, the separation structure 215 may include silicon oxide and polysilicon.

The second circuit element 224 may include a transfer gate TG and active elements 221. The active elements 221 may be transistors including a gate 221a and a source/drain (221b). The transfer gate TG may transfer charges from an adjacent photodiode PD to an adjacent floating diffusion region. The active elements 221 may be various transistors of the pixel circuit described in FIG. 2, such as a driving transistor, a reset transistor, and a select transistor.

The transfer gate TG may be a vertical transfer gate including a portion extending from the first surface 206s1 of the second substrate 206 into the second substrate 206.

The pixel PX described above with reference to FIGS. 1 and 2 may include a photodiode PD, a transfer gate TG, and active elements 221.

The second interconnection structure 227 may include multilayer interconnections located on different height levels, and vias electrically connecting the multilayer interconnections and electrically connecting the multilayer interconnections to the second circuit element 224.

The first insulating structure 118 and the second insulating structure 230 may be in contact with one another and bonded. Each of the first and second insulating structures 118 and 230 may be formed as a multilayer including different types of insulating layers. For example, the second insulating structure 230 may be formed as a multilayer including at least two types of a silicon oxide layer, a low-k dielectric layer, or a silicon nitride layer.

In embodiments, the upper structure 203 may further include a through-electrode penetrating the second substrate 206 and the second insulating structure 230 and partially penetrating the first insulating structure 118. The through-electrode may be in contact with the first interconnection structure 115 and the second interconnection structure 227, and may electrically connect the first interconnection structure 115 to the second interconnection structure 227. In embodiments, the lower structure 103 may include a first joining pad, and the upper structure 203 may include a second joining pad. The first joining pad may be electrically connected to the first interconnection structure 115, and may be coplanar with an upper surface of the first insulating structure 118, and the second joining pad may be electrically connected to the second interconnection structure 227, and may be coplanar with a lower surface of the second insulating structure 230. The first joining pad may be joined to the second joining pad, and may electrically connect the lower structure 103 and the upper structure 203.

The upper structure 203 may further include a first antireflection layer 240 disposed on the second surface 206s2 of the second substrate 206. The first antireflection layer 240 may cover the separation structure 215.

The first antireflection layer 240 may prevent reflection of light that may occur due to a rapid change in refractive index on the second surface 206s2 of the second substrate 206, which may be formed of silicon. The first antireflection layer 240 may adjust a refractive index such that the incident light may proceed to the photodiodes PD with high transmittance. The first antireflection layer 240 may also be referred to as an antireflection structure or an antireflection layer.

The first antireflection layer 240 may have transparency in a visible wavelength, and may include a material having a negative charge for preventing charging by a dangling bond of the second surface 206s2 of the second substrate 206. In addition, the first antireflection layer 240 may include a material of which thickness is adjusted to control a peak of transmittance. The first antireflection layer 240 may include at least one of silicon oxide, aluminum oxide, hafnium oxide, or titanium oxide. The first antireflection layer 240 may be formed as a single layer or a plurality of layers.

The upper structure 203 may include color filters CF. For example, the color filters CF may include color filters CF filtering different colors. For example, the color filters CF may include at least one of green color filters, blue color filters, red color filters, or yellow color filters. In FIGS. 3 and 4, each of the color filters CF may be indicated by a dotted line.

The color filters CF may be disposed on the first antireflection layer 240. The color filters CF may vertically overlap the photodiodes PD, corresponding thereto, respectively. The color filters CF may allow light of a specific wavelength to pass through and reach the photodiodes PD. For example, the color filters CF may be formed of a material in which a pigment including a metal or a metal oxide is mixed into a resin.

The upper structure 203 may further include an upper capping layer 260. The upper capping layer 260 may be disposed on the color filters CF. In embodiments, the upper capping layer 260 may seal a space between the color filters CF. For example, the upper capping layer 260 may cover upper surfaces of the color filters CF, and may not completely fill the space between the color filters CF.

In embodiments, a thickness of the upper capping layer 260 may not be constant. For example, the upper capping layer 260 may include first portions 261 vertically overlapping the color filters CF, and second portions 262 not vertically overlapping the color filters CF. A thickness of each of the second portions 262 may be smaller than a thickness of each of the first portions 261. For example, each of the first portions 261 may have a first thickness T1, and each of the second portions 262 may have a second thickness T2, smaller than the first thickness T1. Lower surfaces 261L of the first portions 261 may be in contact with the upper surfaces of the color filters CF, and lower surfaces 262L of the second portions 262 may be spaced apart from the color filters CF. In embodiments, the lower surfaces 262L of the second portions 262 may include concave surfaces.

In embodiments, the upper capping layer 260 may include a transparent insulating material. For example, the upper capping layer 260 may include silicon oxide.

The upper structure 203 may further include grids 250. The grids 250 may be disposed between the color filters CF, and may space at least a portion of adjacent color filters CF apart from one another. The grids 250 may be formed to have a relatively small refractive index, such that an optical cross-talk phenomenon between adjacent pixels PX may be prevented or reduced. In embodiments, each of the grids 250 may include an air gap AG therein. For example, an upper limit of the air gap AG may be defined by the upper capping layer 260. The second portion 262 of the upper capping layer 260 may overlap the air gap AG in the vertical direction, and the lower surface 262L of the second portion 262 may define the upper limit of the air gap AG.

In embodiments, a lower limit of the air gap AG may be defined by the first antireflection layer 240. For example, the first antireflection layer 240 may include first portions overlapping vertically the color filters CF, and second portions not overlapping vertically the color filters CF. The second portions of the first antireflection layer 240 may overlap vertically the air gap AG, and may define the lower limit of the air gap AG.

In embodiments, a lateral limit of the air gap AG may be defined by the color filters CF. For example, side surfaces of the color filters CF spaced apart with the grid 250 therebetween may define the lateral limit of the air gap AG.

The grid 250 may have the air gap AG in which a refractive index thereof is 1 therein, such that an optical cross-talk phenomenon of the image sensor 1 is prevented or reduced.

In plan view, the grids 250 may extend horizontally between the color filters CF. In embodiments, each of the grids 250 may extend in an X-direction or a Y-direction. For example, in plan view, the grids 250 may have a bar shape. In the present specification, the grids 250 extending in the X-direction may be referred to as first grids 251, and the grids 250 extending in the Y-direction may be referred to as second grids 252. The first grids 251 may be alternately disposed with the second grids 252 in the X-direction and the Y-direction.

Referring further to FIGS. 3 and 4, the first grids 251 and the second grids 252 may be disposed, without being connected to one another, and to be spaced apart from one another. For example, the first grids 251 may include first grid groups GG1 and second grid groups GG2, disposed in rows. The first grid groups GG1 and the second grid groups GG2 may be disposed alternately in the Y-direction.

In embodiments, the first grid groups GG1 may be disposed to be offset from the second grid groups GG2 in the X-direction. For example, the first grids 251 of the first grid groups GG1 may be disposed to be offset from the first grids 251 of the second grid groups GG2 in the X-direction, and may partially overlap one another in the Y-direction. In embodiments, the first grids 251 of the first grid groups GG1 disposed in different rows may be aligned in the Y-direction. The first grids 251 of the second grid groups GG2 disposed in different rows may be aligned in the Y-direction.

The second grids 251 may include third grid groups GG3 and fourth grid groups GG4, disposed in columns. The third grid groups GG3 and the fourth grid groups GG4 may be disposed alternately in the X-direction. The third grid groups GG3 and the fourth grid groups GG4 may intersect with the first grid groups GG1 and the second grid groups GG2.

In embodiments, the third grid groups GG3 may be disposed to be offset from the fourth grid groups GG4 in the Y-direction. For example, the second grids 252 of the third grid groups GG3 may be disposed to be offset from the second grids 252 of the fourth grid groups GG4 in the Y-direction, and may partially overlap in the X-direction. In embodiments, the second grids 252 of the third grid groups GG3 disposed in different columns may be aligned in the Y-direction. The second grids 252 of the fourth grid groups GG4 disposed in different columns may be aligned in the Y-direction.

In embodiments, the first grids 251 of the first grid groups GG1 may not overlap the second grids 252 of the third grid groups GG3 in the Y-direction. For example, each of the second grids 252 of the third grid groups GG3 may extend in the Y-direction between adjacent first grids 251 of the first grid groups GG1 in the X-direction. The first grids 251 of the second grid groups GG2 may overlap the second grids 252 of the third grid groups GG3 in the Y-direction.

In embodiments, the first grids 251 of the second grid groups GG2 may not overlap the second grids 252 of the fourth grid groups GG4 in the Y-direction. For example, each of the second grids 252 of the fourth grid groups GG4 may extend in the Y-direction between adjacent first grids 251 of the second grid groups GG2 in the X-direction. The first grids 251 of the first grid groups GG1 may overlap the second grids 252 of the fourth grid groups GG4 in the Y-direction.

According to embodiments of the present disclosure, only one of the first grid 251 or the second grid 252 may be disposed between four adjacent color filters CF. For example, as illustrated in FIG. 4, the color filters CF may include first to fourth color filters CF1, CF2, CF3, and CF4 adjacent to one another. The first grids 251 may extend between the first color filter CF1 and the third color filter CF3 and between the second color filter CF2 and the fourth color filter CF4. The second grid 252 may extend between the first color filter CF1 and the second color filter CF2 and between the third color filter CF3 and the fourth color filter CF4.

In embodiments, when viewed in plan view, each of the color filters CF may include four protrusions P extending in the horizontal direction. For example, each of the color filters CF may be in contact with two first grids 251 and two second grids 252. Each of the color filters CF may include protrusions P extending between adjacent first grids 251 and adjacent second grids 252.

For example, the first color filter CF1 may include a first protrusion P1 contacting the second color filter CF2 and a second protrusion P2 contacting the third color filter CF3. The second color filter CF2 may include a third protrusion P3 contacting the first color filter CF1, and the third color filter CF3 may include a fourth protrusion P4 contacting the first color filter CF1. The first color filter CF1 may be adjacent to the second color filter CF2 in the X-direction, and the first protrusion P1 and the third protrusion P3 may extend in the X-direction, and may be in contact with one another. The first color filter CF1 may be adjacent to the third color filter CF3 in the Y-direction, and the second protrusion P2 and the fourth protrusion P4 may extend in the Y-direction, and may be in contact with one another. The first protrusion P1 of the first color filter CF1 may be spaced apart from the third color filter CF3 and the fourth color filter CF4. The second protrusion P2 of the first color filter CF1 may be spaced apart from the second color filter CF2 and the fourth color filter CF4.

In embodiments, the adjacent color filters CF may be disposed mirror-symmetrically. For example, the first color filter CF1 and the second color filter CF2 may be disposed to be mirror-symmetrical with respect to a first axis AX1 extending between the first color filter CF1 and the second color filter CF2 in the Y-direction. The first color filter CF1 and the third color filter CF3 may be disposed to be mirror-symmetrical with respect to a second axis AX2 extending between the first color filter CF1 and the third color filter CF3 in the X-direction.

In embodiments, the color filters CF may be disposed in 4-fold symmetry. For example, the first to fourth color filters CF1, CF2, CF3, and CF4 described above may be disposed in 4-fold symmetry. In addition, the grids 250 may be disposed in 4-fold symmetry.

The upper structure 203 may further include micro lenses ML on the upper capping layer 260.

The micro lenses ML may vertically overlap the color filters CF, respectively. In embodiments, the micro lenses ML may vertically overlap one color filter CF, respectively. Alternatively, the micro lenses ML may vertically overlap the plurality of color filters CF. For example, one micro lens among the micro lenses ML may vertically overlap four adjacent color filters CF among the plurality of color filters CF.

Each of the micro lenses ML may have a convex shape in a direction away from the lower structure 103. The micro lenses ML may focus incident light into the photodiodes PD. The micro lenses ML may be formed of a transparent photoresist material or a transparent thermosetting resin material. For example, the micro lenses ML may be formed of a TMR series resin (product of Tokyo Ohka Kogo, Co.) or an MFR series resin (product of Japan Synthetic Rubber Corporation), but are not limited thereto.

The upper structure 203 may further include a passivation layer PL on the micro lenses ML. The passivation layer PL may conformally cover surfaces of the micro lenses ML. The passivation layer PL may include an inorganic oxide.

According to embodiments of the present disclosure, the first grids 251 and the second grids 252 may not be connected, and may be spaced apart from one another. For example, the air gap AG of the grids 251 and 252 may extend only in the X-direction or the Y-direction, and may not have a folded shape. When the air gap AG has a folded shape, the air gap AG may have a relatively large horizontal width at the folded portion, and therefore the upper capping layer 260 should be sufficiently thick. When the upper capping layer 260 is thick, a focal length from the micro lens ML to the photodiode PD may increase, and therefore, there may be a concern that sensitivity between the color filters CF may decrease.

However, according to the embodiments of the present disclosure, the air gap AG may be disposed not to have a folded shape, and therefore, a width in a thickness direction of the air gap AG (for example, a width of the first grid 251 in the Y-direction or a width of the second grid 252 in the X-direction) may be formed relatively small. Therefore, according to the embodiments of the present disclosure, the upper capping layer 260 may be formed to be relatively thin, and sensitivity of the image sensor 1 may be improved.

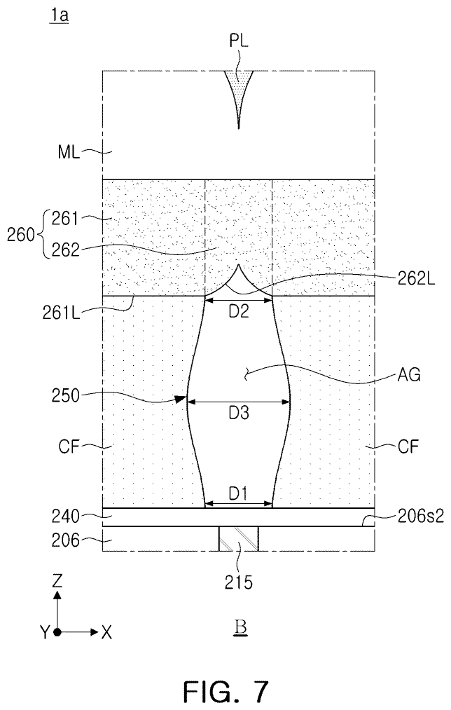

FIGS. 7 to 16 are vertical cross-sectional views of image sensors according to example embodiments.

Referring to FIG. 7, an image sensor la may include a grid 250 between color filters CF and an upper capping layer 260 on the color filters CF. In embodiments, side surfaces of the color filters CF may include concave curves. For example, on lower surfaces of the color filters CF, a distance between adjacent color filters CF may be a first distance D1. On upper surfaces of the color filters CF, a distance between the adjacent color filters CF may be a second distance D2. On an intermediate level between the upper and lower surfaces of the color filters CF, a distance between the adjacent color filters CF may be a third distance D3. The third distance D3 may be smaller than the first distance D1 and the second distance D2. A lower surface 262L of a second portion 262 of the upper capping layer 260 may include a concave curved surface.

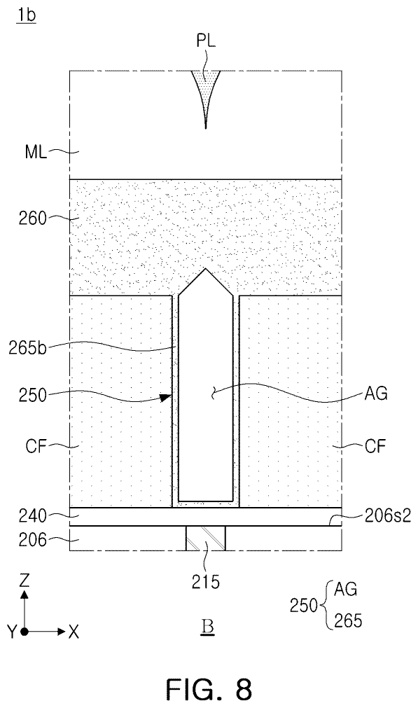

Referring to FIG. 8, an image sensor 1b may include a grid 250 between color filters CF. In embodiments, the grid 250 may further include a lower capping layer 265b covering at least a portion of the color filters CF and defining a lower limit of an air gap AG. For example, the lower capping layer 265b may cover side surfaces of the color filters CF and an upper surface of a first antireflection layer 240. In embodiments, the lower capping layer 265b may extend along the side surfaces of the color filters CF and be connected to an upper capping layer 260. For example, the lower capping layer 265b may include the same material as the upper capping layer 260, and may be formed integrally.

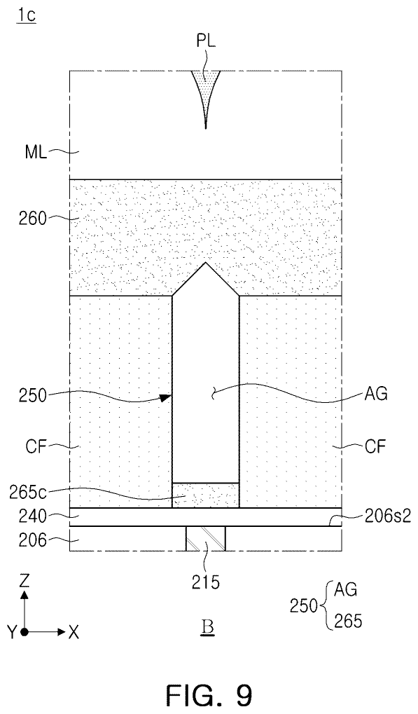

Referring to FIG. 9, an image sensor 1c may include a grid 250 between color filters CF. In embodiments, the grid 250 may further include a lower capping layer 265c covering at least a portion of the color filters CF and defining a lower limit of an air gap AG. For example, the lower capping layer 265c may partially cover side surfaces of the color filters CF. Lower portions of the side surfaces of the color filters CF may be covered by the lower capping layer 265c, and upper portions of the side surfaces of the color filters CF may be exposed by the air gap AG.

The lower capping layer 265c may include at least one of silicon oxide, aluminum oxide, hafnium oxide, or titanium oxide. The lower capping layer 265c may be formed as a single layer or a plurality of layers.

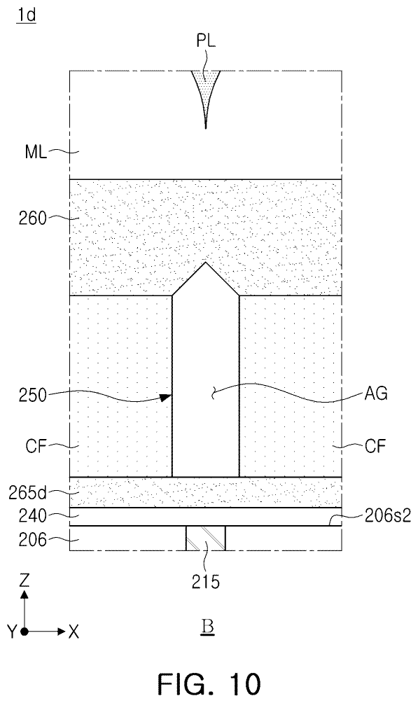

Referring to FIG. 10, an image sensor 1d may include a grid 250 between color filters CF. In embodiments, the grid 250 may further include a lower capping layer 265d covering at least a portion of the color filters CF and defining a lower limit of an air gap AG. The lower capping layer 265d may cover lower surfaces of the color filters CF, and may extend in the horizontal direction. The lower capping layer 265d may include at least one of silicon oxide, aluminum oxide, hafnium oxide, or titanium oxide. The lower capping layer 265d may be formed as a single layer or a plurality of layers.

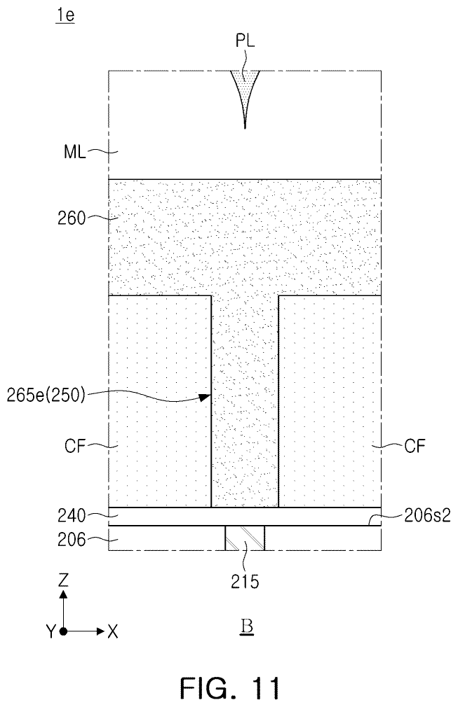

Referring to FIG. 11, an image sensor le may include a grid 250 between color filters CF. In embodiments, the grid 250 may include a lower capping layer 265e filling a space between the color filters CF. For example, the grid 250 may not include an air gap AG. The lower capping layer 265e may fill the space between the color filters CF, and may be connected to an upper capping layer 260. For example, the lower capping layer 265e may include the same material as the upper capping layer 260, and may be formed integrally.

Refractive indices of the lower capping layers illustrated in FIGS. 8 to 11 may be greater than the air gap AG. For example, a difference in refractive indices between the lower capping layers and the color filters CF may be smaller than a difference in refractive indices between the air gap AG and the color filters CF. Therefore, it is possible to prevent or reduce a change in optical path of light transmitted through the grid 250.

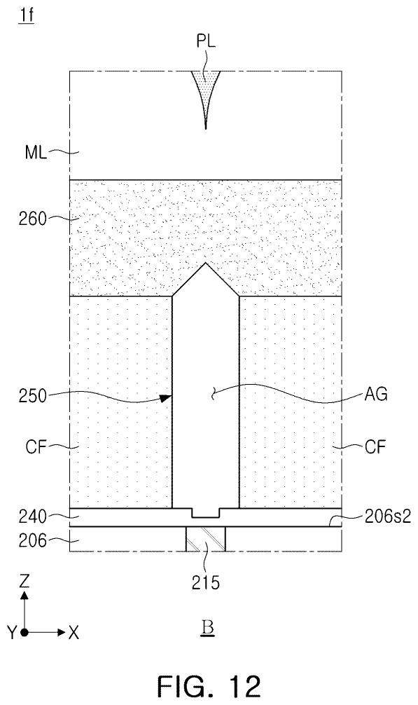

Referring to FIG. 12, an image sensor 1f may include a grid 250 between color filters CF. In embodiments, an air gap AG of the grid 250 may further extend in the vertical direction toward a first antireflection layer 240. For example, an upper surface of a portion of the first antireflection layer 240 vertically overlapping the grid 250 may include a recess. The recess may be exposed by the air gap AG, and may define a lower limit of the air gap AG.

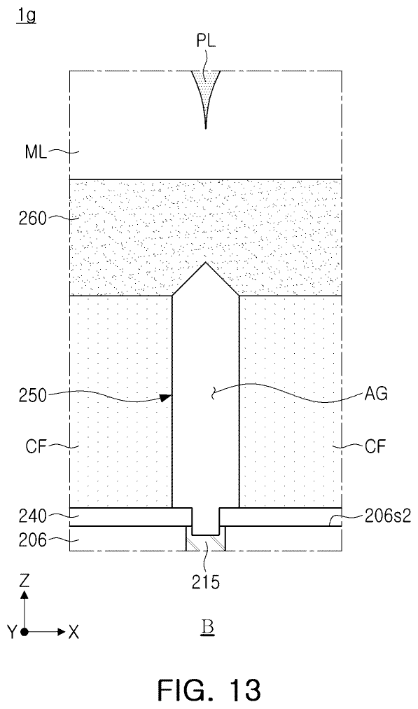

Referring to FIG. 13, an image sensor 1g may include a grid 250 between color filters CF. In embodiments, an air gap AG of the grid 250 may further extend in the vertical direction toward a separation structure 215. For example, a first antireflection layer 240 may be cut, and a side surface of the first antireflection layer 240 may be exposed by the air gap AG. An upper surface of a portion of the separation structure 215 vertically overlapping the grid 250 may include a recess. The recess may be exposed by the air gap AG, and may define a lower limit of the air gap AG.

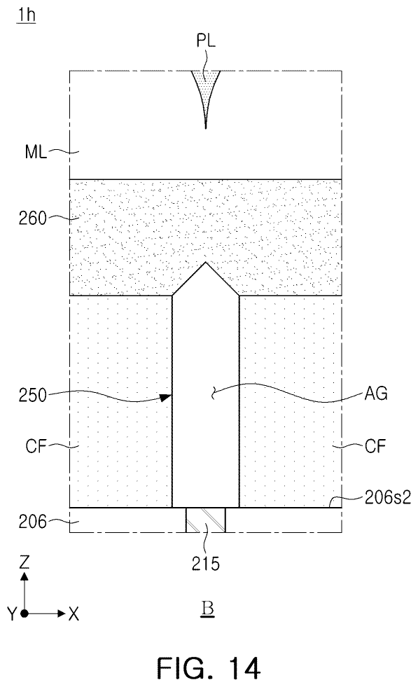

Referring to FIG. 14, unlike the image sensors described above, an image sensor 1h may omit a first antireflection layer 240. For example, a second surface 206s2 of a second substrate 206 may be in contact with color filters CF. The second surface 206s2 of the second substrate 206 and a separation structure 215 may define a lower limit of an air gap AG.

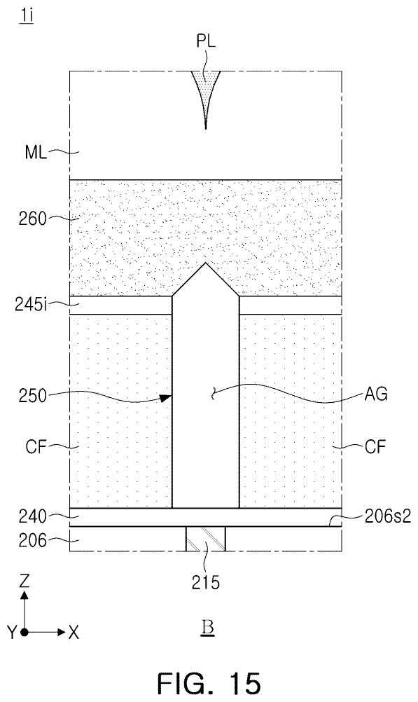

Referring to FIG. 15, an image sensor li may further include a second antireflection layer 245i covering at least one of upper and lower surfaces of an upper capping layer 260. For example, the second antireflection layer 245i may cover a lower surface of the upper capping layer 260 and upper surfaces of color filters CF. A side surface of the color filter CF and a side surface of the second antireflection layer 245i may define a lateral limit of the air gap AG.

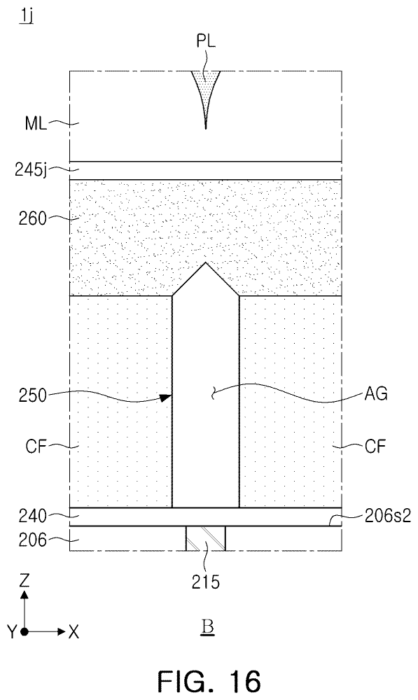

Referring to FIG. 16, an image sensor 1j may further include a second antireflection layer 245j covering at least one of upper and lower surfaces of an upper capping layer 260. For example, the second antireflection layer 245j may cover an upper surface of the upper capping layer 260 and lower surfaces of micro lenses ML.

The second antireflection layers 245i and 245j may include at least one of silicon oxide, aluminum oxide, hafnium oxide, or titanium oxide. The second antireflection layers 245i and 245j may be formed as a single layer or a plurality of layers.

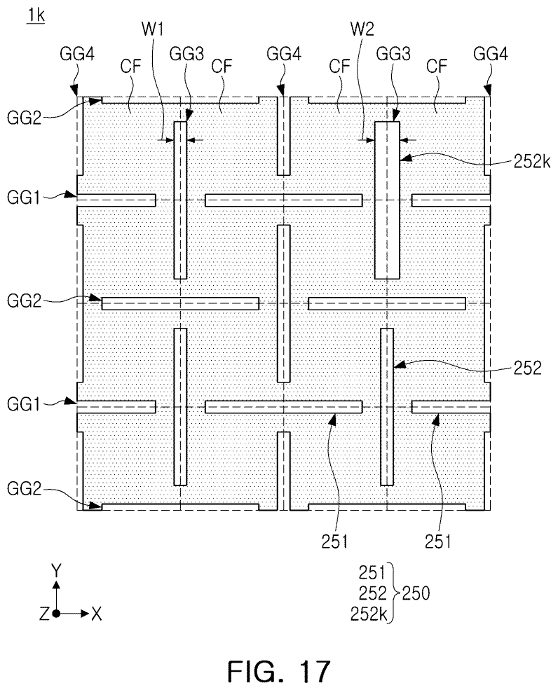

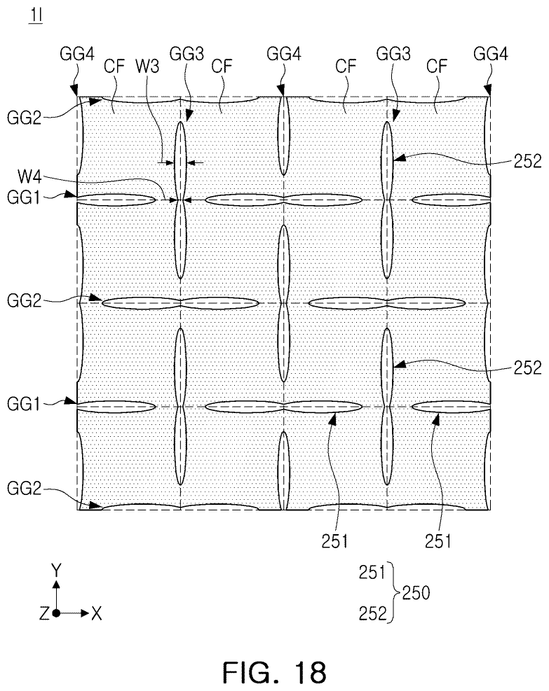

FIGS. 17 and 18 are plan views of image sensors according to example embodiments.

Referring to FIG. 17, an image sensor 1k may include grids 250 between color filters CF. In embodiments, the grids 250 may include grids 250 having different widths in a thickness direction. For example, the grids 250 may include a second grid 252 and a second grid 252k. A width of the second grid 252 in the thickness direction, for example, a horizontal width in the X-direction, may have a first width W1. A width of the second grid 252k in the thickness direction may have a second width W2, greater than the first width W1.

As illustrated in FIG. 17, in some types of color filters CF among green color filters, blue color filters, red color filters, and yellow color filters, to adjust sensitivity or crosstalk, a width of a grid 250 may be adjusted. An array of color filters CF of FIG. 17 is illustrative, and is not limited thereto. First grids 251 according to embodiments may also have various horizontal widths.

Referring to FIG. 18, an image sensor 11 may include grids 250 between color filters CF. In embodiments, a horizontal width in a thickness direction of each of the grids 250 may not be constant. For example, when viewed in plan view, a horizontal width in the thickness direction of central portions of the grids 250 may be smaller than a horizontal width in the thickness direction of end portions of the grids 250. For example, a horizontal width in the X-direction of an end portion of a second grid 252 may have a third width W3, and a horizontal width in the X-direction of a central portion of the second grid 252 may have a fourth width W4, smaller than the third width W3. In addition, a horizontal width in the Y-direction of a central portion of a first grid 251 may be smaller than a horizontal width in the Y-direction of an end portion of the first grid 251.

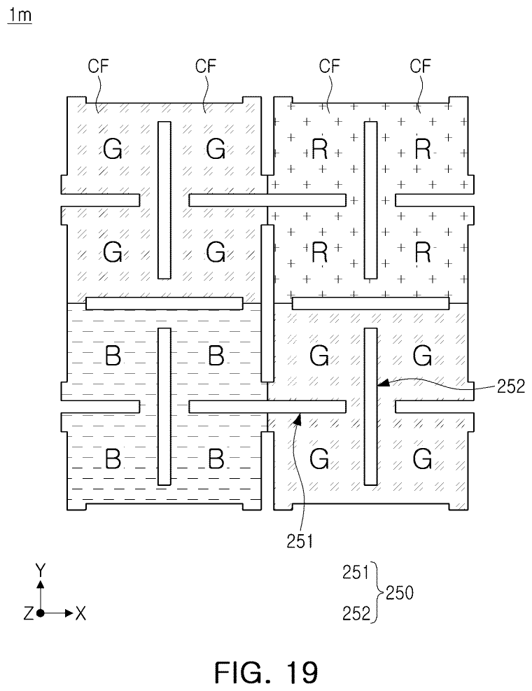

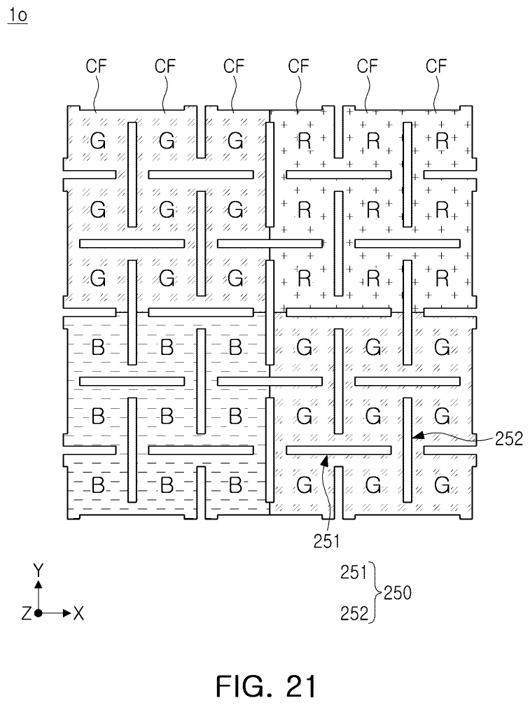

FIGS. 19 and 21 illustrate various arrangements of color filters of an image sensor according to example embodiments.

Referring to FIG. 19, color filters CF of an image sensor 1m may include green color filters G, blue color filters B, and red color filters R. In embodiments, the color filters CF may be disposed in a quad Bayer pattern. For example, the color filters CF may be repeatedly disposed, each of which may be formed as four red color filters R, four green color filters G, and four blue color filters B, each of which may be disposed in a 2×2 matrix. For example, four green color filters G may be disposed in one diagonal direction, and four red color filters R and four blue color filters B may be disposed in the other diagonal direction, respectively, in a unit pattern in a 4×4 array form.

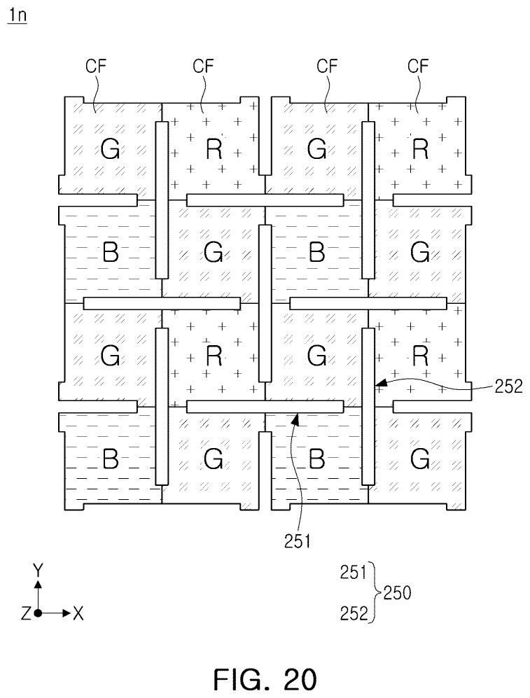

Referring to FIG. 20, color filters CF of an image sensor In may include green color filters G, blue color filters B, and red color filters R. In embodiments, the color filters CF may be disposed in a Bayer pattern. For example, in a unit pattern in a 2×2 array form, two green color filters G may be disposed in one diagonal direction, and one red color filter R and one blue color filter B may be disposed in the other diagonal direction, respectively. For example, green color filters G and red color filters R may be disposed alternately in the X-direction, and green color filters G and blue color filters B may be disposed alternately in the Y-direction.

Referring to FIG. 21, color filters CF of an image sensor 10 may include green color filters G, blue color filters B, and red color filters R. In embodiments, the color filters CF may be disposed in a Nona Pattern. For example, the color filters CF may be repeatedly disposed, each of which may be formed as nine red color filters R, nine green color filters G, and nine blue color filters B, disposed in a 3×3 matrix. For example, nine green color filters G may be disposed in one diagonal direction, and nine red color filters R and nine blue color filters B may be disposed in the other diagonal direction in a unit pattern in a 6×6 array form.

The arrays of the color filters CF in FIGS. 19 to 21 are illustrative, and are not limited thereto. For example, the same type of color filters CF may be disposed in an n X n matrix (where, k may be an integer greater than or equal to 2).

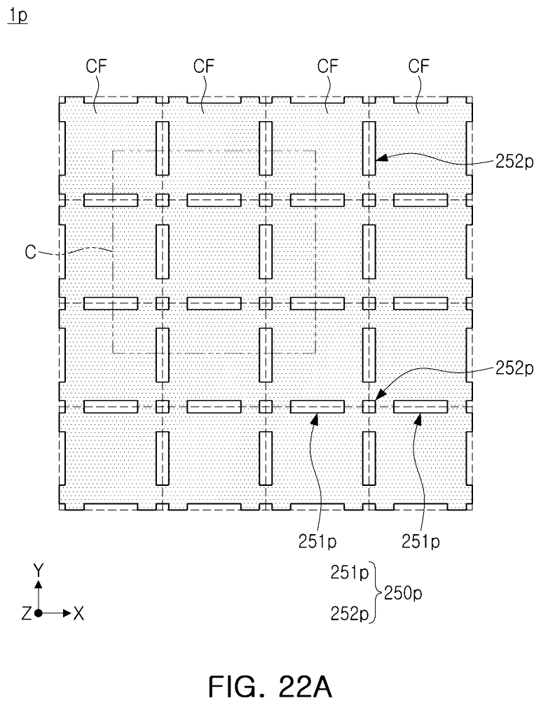

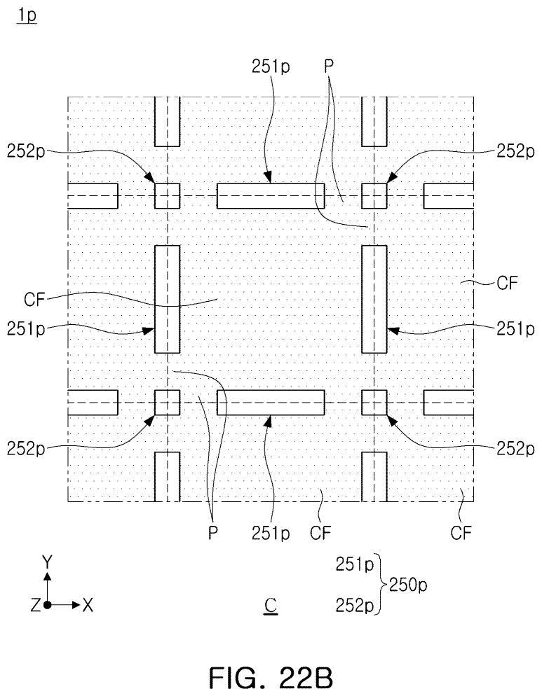

FIG. 22A is a schematic plan view of an image sensor according to example embodiments. FIG. 22B is an enlarged view of the image sensor illustrated in FIG. 22A.

Referring to FIGS. 22A and 22B, an image sensor 1p may include grids 250p between color filters CF. In embodiments, the grids 250p may include first grids 251p and second grids 252p. Each of the first grids 251p may extend in the X-direction or the Y-direction. The first grids 251p may be disposed between two adjacent color filters CF. The second grids 252p may be disposed between the first grids 251p. For example, the second grids 252p may be disposed with the first grids 251p alternately in the X-direction and alternately in the Y-direction. The second grids 252p may be disposed between four adjacent color filters CF.

In embodiments, the first grids 251p may be larger than the second grids 252p. For example, a maximum horizontal width of the first grid 251p may be larger than a maximum horizontal width of the second grids 252p. A length of the first grid 251p extending in the X-direction, in the X-direction, and a length of the first grid 251p extending in the Y-direction, in the Y-direction, may each be larger than the maximum horizontal width of the second grids 252p.

In embodiments, when viewed in plan view, each of the color filters CF may include eight protrusions P extending in the horizontal direction. For example, each of the color filters CF may include protrusions P extending between adjacent first grids 251p and adjacent second grids 252p. Each of the color filters CF may be adjacent to four color filters CF, and adjacent color filters CF may be in contact with two protrusions P.

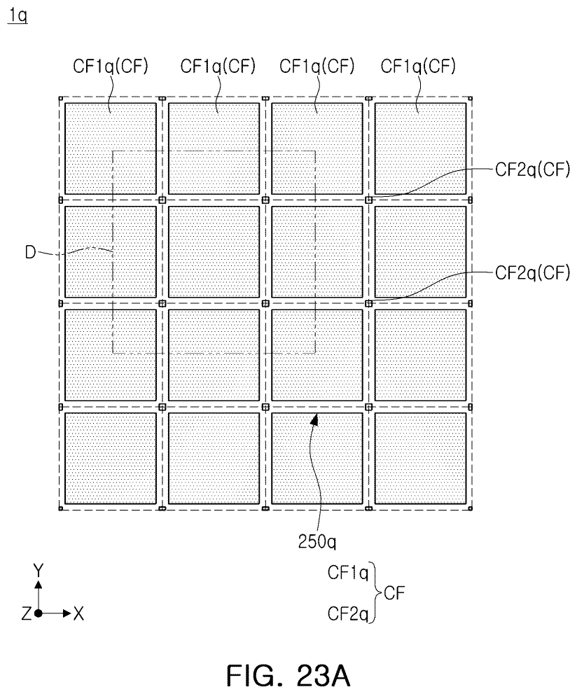

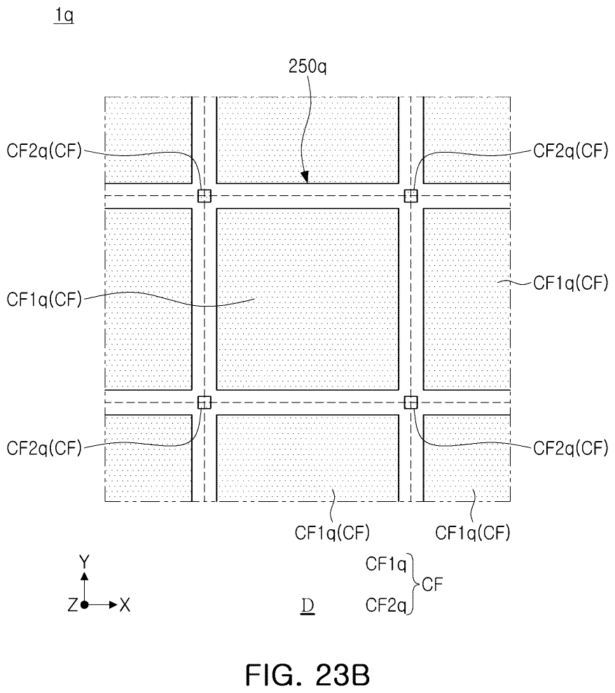

FIG. 23A is a schematic plan view of an image sensor according to example embodiments. FIG. 23B is an enlarged view of the image sensor illustrated in FIG. 23A.

Referring to FIGS. 23A and 23B, an image sensor 1q may include a grid 250q between color filters CF. In embodiments, the grid 250q may extend in the X-direction and the Y-direction between the color filters CF. In embodiments, the color filters CF may include first color filters CF1q and second color filters CF2q. The first color filters CF1q may be spaced apart from one another in the X-direction and the Y-direction, and the grid 250q may be disposed between the first color filters CF1q. The second color filters CF2q may be disposed between four adjacent first color filters CF1q, and may be spaced apart from one another in the X-direction and the Y-direction. The second color filters CF2q may be surrounded by the grid 250q. For example, a size of each of the second color filters CF2q may be smaller than a size of each of the first color filters CF1q. A maximum horizontal width of the second color filters CF2q may be smaller than a horizontal width of the grid 250q.

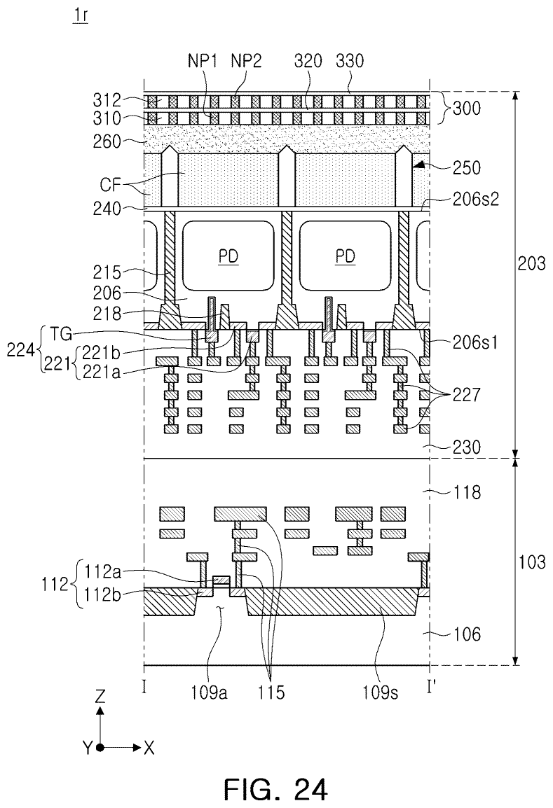

FIG. 24 is a vertical cross-sectional view of an image sensor according to example embodiments.

In embodiments, an image sensor 1r may include a meta-optical structure 300 on an upper capping layer 260. In this case, the meta-optical structure 300 refers to an optical structure based on meta-optics, and may also be referred to as a meta-surface or a meta-lens.

In this embodiment, the meta-optical structure 300 may be disposed on a second surface 206s2 of a second substrate 206, which may be an incident surface side, and may be configured to disperse incident light according to wavelength (e.g., color) and to focus the dispersed light onto photodiodes PD of different pixels PX.

The meta-optical structure 300 may be a multilayer structure including a plurality of mold layers 310 and 312, and may include nano-prism patterns NP1 and NP2 which may be nano-scale structures (e.g., post structures) disposed in the plurality of mold layers 310 and 312. Specifically, the meta-optical structure 300 may include a first mold layer 310 on the upper capping layer 260, a second mold layer 312 on the first mold layer 310, first nano-prism patterns NP1 disposed on the same level as the first mold layer 310, and second nano-prism patterns NP2 disposed on the same level as the second mold layer 312. The first nano-prism patterns NP1 may be disposed in the same manner as or in a different manner from the second nano-prism patterns NP2. According to embodiments, the nano-prism patterns may be formed as a single layer or a plurality of layers.

The first and second mold layers 310 and 312 may include a material having a low refractive index. For example, the first and second mold layers 310 and 312 may include a transparent inorganic material such as silicon oxide, silicon oxynitride, silicon nitride, silicon carbonate, or silicon carbonitride. The first and second nano-prism patterns NP1 and NP2 may include a material having a high refractive index. For example, the first and second nano-prism patterns NP1 and NP2 may include a transparent inorganic material such as titanium oxide, silicon nitride, niobium oxide, tantalum oxide, aluminum oxide, or hafnium oxide.

In embodiments, the meta-optical structure 300 may further include an etching stop layer 320. The etching stop layer 320 may cover upper surfaces of the first mold layer 310 and the first nano-prism patterns NP1, and may cover lower surfaces of the second mold layer 320 and the second nano-prism patterns NP2. The etching stop layer 320 may include, for example, aluminum oxide. According to embodiments, the etching stop layer 320 may be omitted.

In embodiments, the meta-optical structure 300 may further include an antireflection layer 330. The antireflection layer 330 may cover upper surfaces of the second mold layer 320 and the second nano-prism patterns NP2. The antireflection layer 330 may include at least one of silicon oxide, aluminum oxide, hafnium oxide, or titanium oxide. The antireflection layer 330 may be formed as a single layer or a plurality of layers. According to embodiments, the antireflection layer 330 may be omitted.

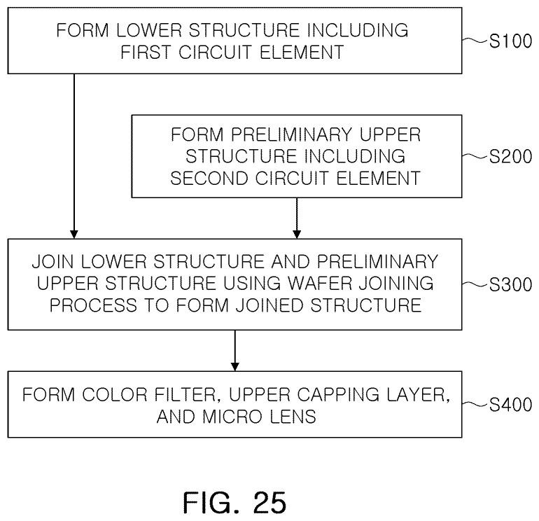

FIG. 25 is a flow chart illustrating a method of manufacturing an image sensor according to example embodiments.

Referring to FIG. 25, a method of manufacturing an image sensor according to example embodiments may include forming a lower structure 103 including a first circuit element 112 (S100), forming a preliminary upper structure 203p including a second circuit element 224 (S200), joining the lower structure 103 and the preliminary upper structure 203p using a wafer joining process to form a joined structure (103 and 203p) (S300), and forming a color filter CF, an upper capping layer 260, and a micro lens ML (S400).

The forming a lower structure 103 including a first circuit element 112 (S100) may include forming a first circuit element 112 and a first interconnection structure 115 on a first substrate 106, and forming a first insulating structure 118 covering the first circuit element 112 and the first interconnection structure 115 on the first substrate 106.

The forming a preliminary upper structure 203p including a second circuit element 224 (S200) may include forming a second circuit element 224 and a second interconnection structure 227 on a first surface 206s1 of a second substrate 206, and forming a second insulating structure 230 covering the second circuit element 224 and the second interconnection structure 227 on the first surface 206s1 of the second substrate 206. The forming a preliminary upper structure 203p including a second circuit element 224 (S200) may further include, before forming the second circuit element 224, forming a separation structure 215 in the second substrate 206, and forming a photodiode PD in the second substrate 206 by an ion implantation process. The forming a preliminary upper structure 203p including a second circuit element 224 (S200) may be performed as a separate process from the forming a lower structure 103 including a first circuit element 112 (S100).

The lower structure 103 and the preliminary upper structure 203p may be joined by a wafer joining process to form a joined structure (103 and 203p) (S300). After the joined structure (103 and 203p) is formed, a planarization process may be further performed such that the separation structure 215 is exposed.

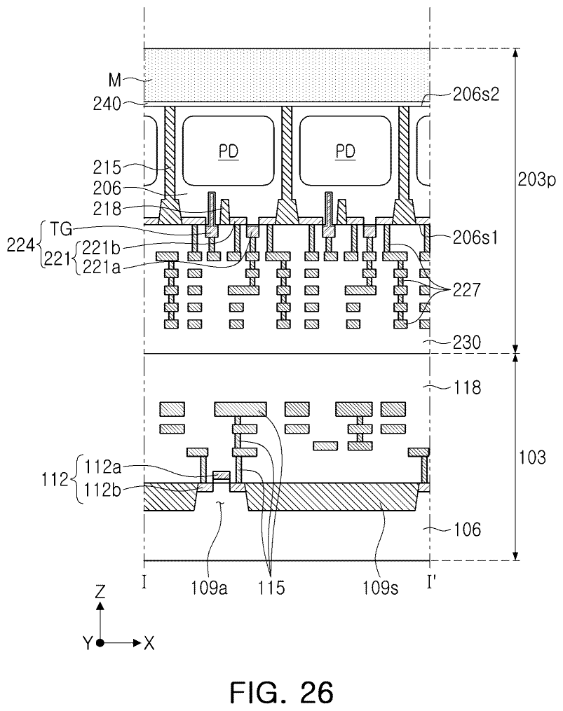

FIGS. 26 to 28 are cross-sectional views illustrated according to a process sequence illustrating a method of manufacturing an image sensor according to example embodiments. Specifically, FIGS. 26 to 28 are vertical cross-sectional views corresponding to FIG. 5, respectively. Referring to FIGS. 26 to 28, forming a color filter CF, an upper capping layer 260, and a micro lens ML on the preliminary upper structure 203p (S400) will be described. According to embodiments, before forming the color filter CF, a first antireflection layer 240 may be formed on a second surface 206s2 of a second substrate 206.

Referring to FIG. 26, a color filter material layer M may be formed on a first antireflection layer 240. The color filter material layer M may cover the first antireflection layer 240, and may be disposed to vertically overlap photodiodes PD. In embodiments, a plurality of color filter material layers M may be formed on the first antireflection layer 240. For example, as illustrated in FIGS. 19 to 21, to form color filters CF of different colors, a first color filter material layer may be formed first. After partially etching the first color filter material layer such that a portion of the first antireflection layer 240 is exposed, a second color filter material layer may be formed in a space from which the first color filter material layer is removed. After partially etching the first color filter material layer and/or the second color filter material layer such that a portion of the first antireflection layer 240 is exposed, a third color filter material layer may be formed in a space from which the first color filter material layer and/or the second color filter material layer is removed.

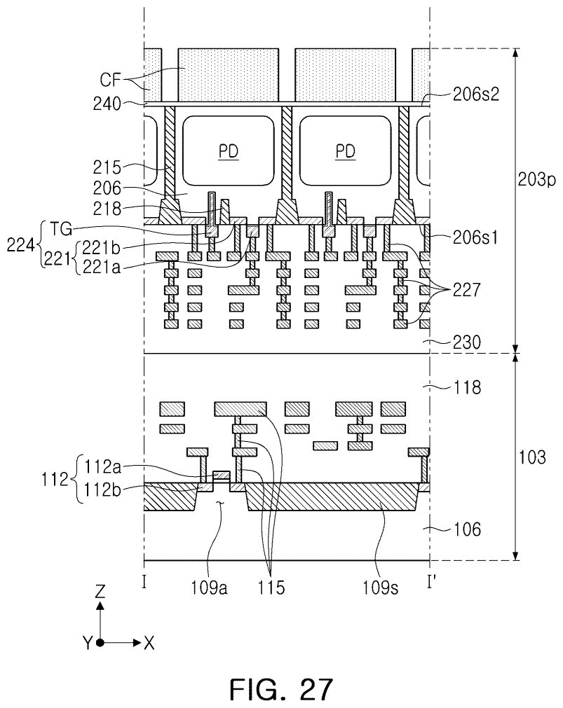

Referring to FIG. 27, color filters CF may be formed by patterning the color filter material layer M. The color filters CF may be patterned, similarly to the embodiments illustrated in FIGS. 3, 17, and 18, and FIGS. 22A to 23B. For example, adjacent color filters CF may be disposed mirror-symmetrically. In addition, each of the color filters CF may include protrusions contacting the adjacent color filter CF, and the color filters CF may be disposed in 4-fold symmetry.

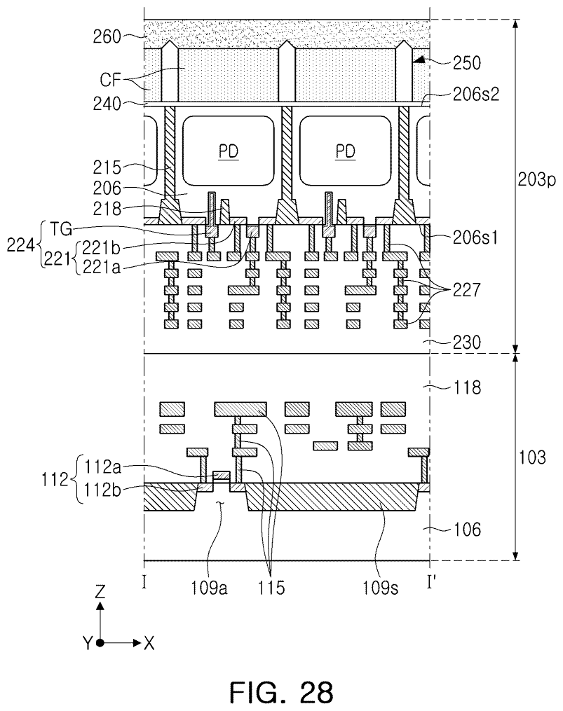

Referring to FIG. 28, an upper capping layer 260 covering the color filters CF may be formed. The upper capping layer 260 may be formed using a deposition method such as a chemical vapor deposition method or an atomic layer deposition method. In embodiments, the upper capping layer 260 may cover upper surfaces of the color filters CF, and may not completely fill a space between the color filters CF. The color filters CF and the upper capping layer 260 may define a grid 250. For example, forming the upper capping layer 260 covering the color filters CF may include forming the grid 250. In embodiments, the grid 250 may be composed of an air gap AG. According to embodiments, as illustrated in FIGS. 8, 9, and 11, the grid 250 may include lower capping layers 265b, 265c, and 265e. According to embodiments, before the color filter material layer M is formed, a lower capping layer 265d may be formed. For example, as illustrated in FIG. 10, the lower capping layer 265d may cover lower surfaces of the color filters CF.

According to embodiments, second antireflection layers 245i and 245j may be formed, before or after the upper capping layer 260 is formed, as illustrated in FIGS. 15 and 16. The second antireflection layers 245 i and 245 j may cover lower and upper surfaces of the upper capping layer 260, respectively.

Referring back to FIG. 5, a micro lens ML and a passivation layer PL may be formed on the upper capping layer 260 to form an upper structure 203, and the image sensors described with reference to FIGS. 3 to 24 may be manufactured.

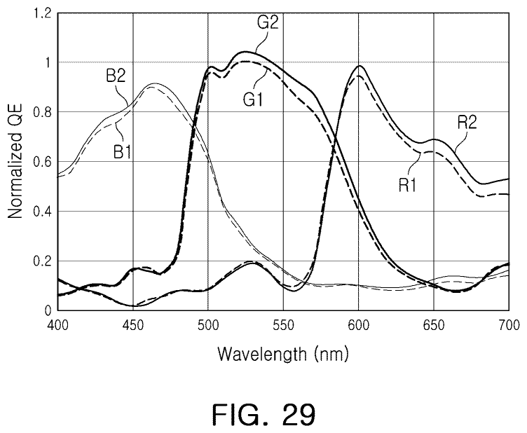

FIG. 29 is a graph illustrating quantum efficiency (QE) for blue light, green light, and red light according to wavelength in an image sensor according to an inventive example and a comparative example. B1, G1, and R1 represent quantum efficiencies for blue light, green light, and red light in an image sensor according to a comparative example. B2, G2, R2 represent quantum efficiencies for blue light, green light, and red light in the image sensor according to the inventive example. In this case, the comparative example may be a structure in which a second grid 252p is omitted from the array of color filters CF of FIG. 22A.

Referring to FIG. 29, quantum efficiencies for blue light, green light, and red light increased in the inventive example, as compared to the comparative example. Specifically, quantum efficiency of blue light increased by 1.6% in the inventive example, as compared to the comparative example, a quantum efficiency of green light increased by 3.8% in the inventive example, as compared to the comparative example, and a quantum efficiency of red light increased by 4.2% in the inventive example, as compared to the comparative example. Sensitivity for blue light increased by 3.7% in the inventive example, as compared to the comparative example, sensitivity for green light increased by 4.9% in the inventive example, as compared to the comparative example, and sensitivity for red light increased by 1.8% in the inventive example, as compared to the comparative example. Optical crosstalk between the color filters CF decreased by 0.8%.

A method for manufacturing an image sensor according to example embodiments may include forming a lower structure including a first circuit element on a first substrate; forming a preliminary upper structure including a second circuit element on a first surface of a second substrate; joining the lower structure and the preliminary upper structure using a wafer joining process to form a joined structure; and forming color filters and an upper capping layer on the preliminary upper structure. The forming an upper capping layer may include forming grids including air gaps between the color filters. The grids include first grids extending in a first horizontal direction and arranged in a plurality of rows, and second grids extending in a second horizontal direction, intersecting the first horizontal direction, and arranged in a plurality of columns. The first grids and the second grids may be alternately disposed in the first horizontal direction and the second horizontal direction.

The forming color filters may include forming a color filter material layer on a second surface of the second substrate, opposite to the first surface, and patterning the color filter material layer.

The upper capping layer may be formed on the color filters, the color filters may define lateral limits of the air gaps, and the upper capping layer may define upper limits of the air gaps.

The first grids may include a first grid group disposed in a first row, and a second grid group disposed in a second row, adjacent to the first row. The second grids may include a third grid group disposed in a first column, intersecting the first row and the second row, and a fourth grid group disposed in a second column, adjacent to the first column. The first grid group may be disposed to be offset from the second grid group in the first horizontal direction.

The first grids of the first grid group may partially overlap first grids corresponding thereto, respectively, among the first grids of the second grid group, in the second horizontal direction.

The third grid group may be disposed to be offset from the fourth grid group in the second horizontal direction.

The first grids of the first grid group may not overlap the second grids of the third grid group in the second horizontal direction.

In plan view, end portions of the second grids may have a first width in the first horizontal direction, respectively, and central portions of the second grids may have a second width, smaller than the first width, in the first horizontal direction, respectively.

The preliminary upper structure may include a first antireflection layer extending between the second substrate and the color filters, and the first antireflection layer may define lower limits of the air gaps.

Side surfaces of the color filters may include concave curved surfaces.

According to embodiments of the technical idea of the present disclosed concepts, an upper capping layer on a grid may be formed to be relatively thin, and sensitivity of an image sensor may be improved. In addition, first grids and second grids may be alternately disposed to reduce optical crosstalk between color filters.

Various advantages and effects of the present disclosed concepts may not be limited to the above-described contents, and will be more easily understood in the process of explaining specific embodiments.

While example embodiments have been illustrated and described above, it will be apparent to those skilled in the art that modifications and variations could be made without departing from the scope of the present disclosed concepts as defined by the appended claims.

What is claimed is:

1. An image sensor comprising:
photodiodes disposed in a substrate;
a separation structure disposed in the substrate and between the photodiodes;
color filters disposed on the substrate and the separation structure;
grids disposed between the color filters and including air gaps, wherein the grids include first grids extending in a first horizontal direction and arranged in a plurality of rows, and second grids extending in a second horizontal direction, intersecting the first horizontal direction, and arranged in a plurality of columns; and
an upper capping layer covering upper surfaces of the color filters and the grids,
wherein the first grids and the second grids are alternately disposed in the first horizontal direction and the second horizontal direction,
the first grids include a first grid group disposed in a first row, and a second grid group disposed in a second row, adjacent to the first row,
the second grids include a third grid group disposed in a first column, intersecting the first row and the second row, and a fourth grid group disposed in a second column, adjacent to the first column, and
the first grid group is disposed to be offset from the second grid group in the first horizontal direction.

2. The image sensor of claim 1, wherein the first grids of the first grid group partially overlap first grids corresponding thereto, respectively, among the first grids of the second grid group, in the second horizontal direction.

3. The image sensor of claim 1, wherein the third grid group is disposed to be offset from the fourth grid group in the second horizontal direction.

4. The image sensor of claim 3, wherein the second grids of the third grid group partially overlap second grids corresponding thereto, respectively, among the second grids of the fourth grid group, in the first horizontal direction.

5. The image sensor of claim 1, wherein the first grids of the first grid group do not overlap the second grids of the third grid group in the second horizontal direction.

6. The image sensor of claim 1, wherein:
the upper capping layer includes first portions overlapping the color filters in a vertical direction, and second portions overlapping the air gaps in the vertical direction,
at least one of the first portions has a first thickness, and
each of the second portions has a second thickness, smaller than the first thickness.

7. The image sensor of claim 1, wherein side surfaces of the color filters include concave curved surfaces.

8. The image sensor of claim 1, further including a first antireflection layer extending between the substrate and the color filters and between the separation structure and the color filters,
wherein the first antireflection layer defines a lower limit of the air gaps.

9. The image sensor of claim 8, further including a second antireflection layer covering at least one of an upper surface or a lower surface of the upper capping layer.

10. The image sensor of claim 1, wherein each of the grids further includes a lower capping layer covering at least a portion of the color filters and defining a lower limit of each of the air gaps.

11. The image sensor of claim 10, wherein the lower capping layers extend along side surfaces of the color filters and are connected to the upper capping layer.

12. The image sensor of claim 10, wherein:
the lower capping layers cover lower portions of side surfaces of the color filters, and
upper portions of the side surfaces of the color filters are exposed by the air gaps.

13. The image sensor of claim 10, wherein the lower capping layers extend in a horizontal direction along lower surfaces of the color filters.

14. The image sensor of claim 1, wherein, in plan view, end portions of the second grids have a first width in the first horizontal direction, respectively, and
central portions of the second grids have a second width, smaller than the first width, in the first horizontal direction, respectively.

15. An image sensor comprising:
photodiodes disposed in a substrate;
a separation structure disposed in the substrate and between the photodiodes;
color filters disposed on the substrate and the separation structure;
grids disposed between the color filters and including air gaps, wherein the grids include first grids extending in a first horizontal direction and arranged in a plurality of rows, and second grids extending in a second horizontal direction, intersecting the first horizontal direction, and arranged in a plurality of columns; and
an upper capping layer covering upper surfaces of the color filters and the grids,
wherein the first grids and the second grids are alternately disposed in the first horizontal direction and the second horizontal direction,
the color filters include a first color filter, a second color filter, adjacent to the first color filter in the first horizontal direction, and a third color filter, adjacent to the first color filter in the second horizontal direction, intersecting the first horizontal direction,
the first color filter includes a first protrusion contacting the second color filter and extending in the first horizontal direction, and a second protrusion contacting the third color filter and extending in the second horizontal direction,
the first protrusion of the first color filter is spaced apart from the third color filter,
the second protrusion of the first color filter is spaced apart from the second color filter, and
the first color filter and the second color filter are mirror-symmetrical with respect to a central axis in the second horizontal direction between the first color filter and the second color filter.

16. The image sensor of claim 15, wherein the first color filter and the third color filter are mirror-symmetrical with respect to a central axis in the first horizontal direction between the first color filter and the third color filter.

17. The image sensor of claim 15, wherein the second color filter includes a third protrusion contacting the first color filter and extending in the first horizontal direction.

18. The image sensor of claim 15, wherein the third color filter includes a fourth protrusion contacting the first color filter and extending in the second horizontal direction.

19. The image sensor of claim 15, wherein the color filters further include a fourth color filter adjacent to the first color filter, overlapping the second color filter in the second horizontal direction, and overlapping the third color filter in the first horizontal direction,
wherein the first to fourth color filters are disposed in 4-fold symmetry.

20. An image sensor comprising:
a lower structure including a first circuit element; and
an upper structure joined to the lower structure on the lower structure,
wherein the upper structure includes:
a substrate including a first surface and a second surface, opposite to one another;
photodiodes disposed in the substrate;
a separation structure disposed in the substrate and between the photodiodes;
a second circuit element between the first surface of the substrate and the lower structure;
a first antireflection layer disposed on the second surface of the substrate and the separation structure;
color filters disposed on the first antireflection layer;
grids disposed between the color filters and including air gaps, wherein the grids include first grids extending in a first horizontal direction and arranged in a plurality of rows, and second grids extending in a second horizontal direction, intersecting the first horizontal direction, and arranged in a plurality of columns; and
an upper capping layer covering upper surfaces of the color filters and the grids,
wherein the first grids and the second grids are alternately disposed in the first horizontal direction and the second horizontal direction,
the first grids include a first grid group disposed in a first row, and a second grid group disposed in a second row, adjacent to the first row,
the second grids include a third grid group disposed in a first column, intersecting the first row and the second row, and a fourth grid group disposed in a second column, adjacent to the first column, and
the first grid group is disposed to be offset from the second grid group in the first horizontal direction.
